(19) United States
(12) Patent Application Publication
(10) Pub. No.: US 2025/0266801 A1
(43) Pub. Date: Aug. 21, 2025

(54) LATERALLY-DOPED MEMS RESONATOR WITH PIEZOELECTRIC LAYER

(71) Applicant: SiTime Corporarion, Santa Clara, CA (US)

(72) Inventors: Michael Julian Daneman, Campbell, CA (US); Charles I. Grosjean, Los Gatos, CA (US); Aaron Partridge, Cupertino, CA (US); Paul M. Hagelin, Saratoga, CA (US)

(21) Appl. No.: 18/991,881

(22) Filed: Dec. 23, 2024

Related U.S. Application Data
(63) Continuation of application No. 15/912,551, filed on Mar. 5, 2018.
Application No. 15/912,551 is a continuation-in-part of application No. 15/897,135, filed on Feb. 14, 2018, now Pat. No. 10,696,547.
(60) Provisional application No. 62/466,437, filed on Mar. 3, 2017.
(60) Provisional application No. 62/459,017, filed on Feb. 14, 2017.

(51) Int. Cl. H03H 9/02; B81B 7/00; B81B 7/02; B81C 1/00; H03H 9/13; H03H 9/15

(52) U.S. Cl. CPC H03H 9/02244; B81B 7/0006; B81B 7/02; B81C 1/0069; H03H 9/131; H03H 9/15; H03H 2009/155

(57) ABSTRACT

A semiconductor device includes a first silicon layer with first and second regions of substantially different dopant concentration and a resonant MEMS member formed in the first region. A piezoelectric layer is disposed over the resonant MEMS member and conductive material is disposed over the piezoelectric layer and patterned to form first and second electrodes.

### CROSS-REFERENCE TO RELATED APPLICATIONS

This application hereby claims priority to U.S. Provisional Patent Application No. 62/466,437 filed Mar. 3, 2017, and is a continuation-in-part of U.S. application Ser. No. 15/897,135 filed Feb. 14, 2018, which claims priority to U.S. Provisional Patent Application No. 62/459,017 filed Feb. 14, 2017. Each of the foregoing applications is hereby incorporated by reference in its entirety.

### TECHNICAL FIELD

The disclosure herein relates to microelectromechanical systems (MEMS).

### INTRODUCTION

MEMS structures are conventionally sealed in a low-pressure or controlled-pressure chamber through growth of an epitaxial silicon lid, a high-temperature deposition process that may degrade temperature-sensitive materials and/or result in undesired deposition in emerging MEMS solutions.

### DRAWINGS

The various embodiments disclosed herein are illustrated by way of example, and not by way of limitation, in the figures of the accompanying drawings and in which like reference numerals refer to similar elements and in which:

FIG. 1 illustrates an embodiment of a MEMS device in which oxide-release vents are sealed via metal-seal deposition at vent openings in a silicon lid-layer;

FIG. 2 illustrates an embodiment of a MEMS device having metal-sealed oxide-release vents and tapered contact vias;

FIG. 3 illustrates an exemplary fabrication process with respect to the MEMS embodiment of FIG. 1;

FIG. 4 illustrates an exemplary fabrication process with respect to the MEMS embodiment of FIG. 2;

FIGS. 5 and 6 illustrate alternative embodiments in which oxide in a MEMS cavity is released through relatively small capillary passageways extending between the MEMS cavity and larger through-lid vents;

FIGS. 7 and 8 illustrate exemplary fabrication processes corresponding to the narrow-passageway oxide-release vents shown in FIGS. 5 and 6, respectively;

FIGS. 9-11 illustrate examples of process efficiency achieved through concurrent feature formation with respect to the capillary oxide-vent embodiments of FIGS. 5 and 6

FIG. 12 illustrates an embodiment of a MEMS device having a laterally-doped, piezoelectrically-actuated MEMS resonator;

FIGS. 13 and 14 illustrate exemplary processes for implementing the MEMS depicted in FIG. 12; and

FIG. 15 illustrates an embodiment of a MEMS device having two laterally-doped MEMS resonators.

### DETAILED DESCRIPTION

In various embodiments disclosed herein, vents through which an etchant enters to remove sacrificial oxide and thereby define (release) a MEMS element are plugged through strategic material deposition without the high process temperatures and/or inadvertent material depositions associated with conventional epitaxial lid formation. In a number of embodiments, for example, oxide-release vents formed within a silicon lid layer are plugged by metal deposition (e.g., sputtered, evaporated or chemical-vapor-deposited (CVD) metal) at less than half the temperature typically required by epitaxial silicon growth, permitting application with thermally sensitive thin piezo-electric films (e.g., aluminum-nitride) and/or avoiding undesired material deposition onto (or roughening or other degrading of) such films or other material layers. In other embodiments, oxide-release vents are formed with relatively narrow lateral passageways that avoid line-of-sight access into the MEMS chamber and/or narrow vertical passageways that, in either case, may be plugged with no or negligible sealant deposition within the MEMS chamber. In yet other embodiments, process efficiencies are realized through concurrent formation of oxide-release vents, contact-via trenches and isolation trenches (or any subset thereof), and/or concurrent disposition of material(s) within such trenches and release vents.

In further embodiments presented herein, doping (including degenerate doping) depth for a thermal drive of a given duration is increased by etching or otherwise forming chamber-defining slots within device-layer silicon and depositing a dopant-source film on the sidewalls of the slots prior to the thermal drive. Through this lateral doping approach (which may be combined with surface-layer doping) the diffusion time is only limited by the spacing of the slots rather than the thickness of the silicon film. The slots may also serve a dual purpose—not only enabling more rapid (or deeper) doping, but also defining the silicon MEMS structure of the resonator (i.e., defining sides of the silicon portion of the resonant MEMS structure).

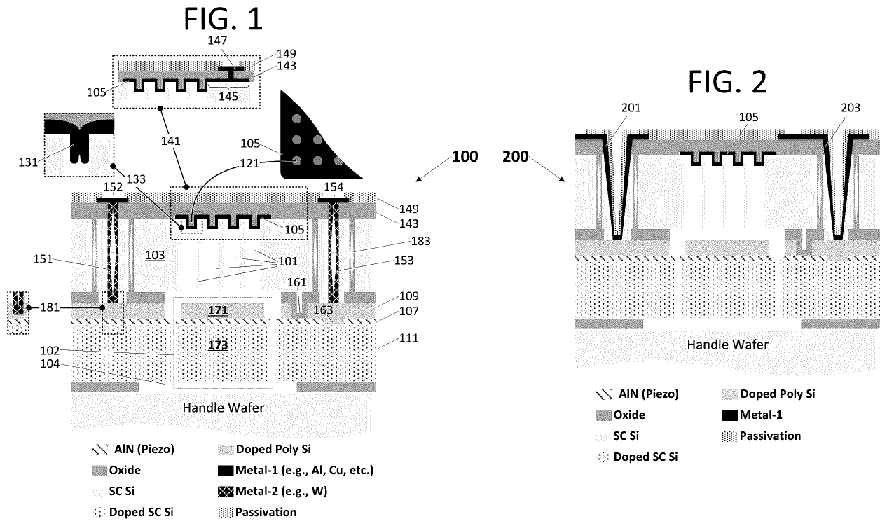

FIG. 1 illustrates an embodiment of a MEMS device 100 in which oxide-release vents 101 are sealed (plugged, blocked, closed-off, etc.) via metal-seal deposition (105) at vent openings in silicon lid-layer 103. In general, metal seal 105 is formed by metal sputtering (e.g., copper (Cu) or aluminum—any practical metal/metal-alloy and deposition process may be used) at a temperature less than 400 degrees Celsius (° C.) and thus less than half the temperature required (typically above 1000° C.) for silicon epitaxy. In the exemplary piezo-actuated MEMS resonator device shown, sealing oxide-release vents 101 through low-temperature metal deposition avoids degrading (damaging, destroying) heat-intolerant piezoelectric layer 107 (e.g., aluminum nitride or lead-zirconium-titanate, though other piezoelectric materials may be used) and also avoids undesired sealant deposition on the doped polysilicon electrode layer 109 and piezoelectric layer 107 which may otherwise degrade those materials (e.g., erode or roughen the polysilicon) and/or bridge the void between the MEMS resonator 102 and surrounding field area (resulting in electrical short-circuit, mechanical disruption, etc.). In other embodiments, including those lacking heat-intolerant material layers (e.g., electrostatically actuated MEMS resonators, MEMS accelerometer masses, MEMS thermistors, etc.), oxide-release vents 101 and lid-silicon metal seal 105 may be strategically positioned to avoid sealant intrusion into the MEMS chamber (i.e., cavity 104, again avoiding undesired mechanical disruption or electrical short-circuit. Accordingly, while the exemplary piezo-actuated resonator structure shown in FIG. 1 (piezoelectric layer sandwiched between doped single-crystal silicon and doped polysilicon) is carried forward in various examples herein, the oxide-vent sealing structures and processes may, in all cases, be applied with respect to MEMS structures formed from other material stacks, single-layer structures (e.g., MEMS resonators or other structures constituted by a single material layer) and multi-layer structures that lack a piezoelectric material layer and/or doped or conductive material layer.

Still referring to FIG. 1, oxide-release vents 101 may be specifically sized (i.e., aperture with specific cross-sectional area as shown by the exemplary circular geometry in top-view 121) to enable a desired metal ingress/fill as shown by the sealed region 131 in detail view 133. For example (and without limitation), in sputtered-metal seal implementations (e.g., Cu, Al, etc.), vent/aperture diameter (or cross-sectional area) may be defined by lithographic patterning to yield a dimension of less than 2 microns ( [symbol] m) and a depth-to-width aspect-ratio of 5 or greater. Further, the metal vent cover (vent cap) may be electrically coupled to an electrical contact (e.g., a ground contact) as shown in detail view 141. In that case, a relatively shallow electrical via may be formed through surface oxide 143 to interconnect vent seal 105 (which may include a lateral extension 145 for that purpose) with metal contact feature 147, itself exposed through an opening in passivation layer 149.

In the FIG. 1 embodiment, electrical vias 151 and 153 extend through the lid-layer silicon 103 to contact sub-surface structures (e.g., MEMS resonator drive/sense electrode(s), MEMS resonator-bias electrode(s), thermistor terminals, MEMS accelerometer-mass bias/sense electrodes, etc.). In the specific piezo-actuated resonator implementation shown, polysilicon layer 109 and device-layer single-crystal silicon 111 are sufficiently doped (e.g., degenerately doped) to serve as electrical conductors, so that via 151 extends from a surface contact 152 to a first actuation electrode in polysilicon layer 109 while via 153 extends from surface contact 154 to a second actuation electrode in single-crystal silicon layer 111 (i.e., formed by interconnection of a region of polysilicon layer 109 isolated by oxide-lined channel 161 to single-crystal silicon layer 111 through opening 163 in piezoelectric layer 107). Though not specifically visible in the depicted cross-section, the region of polysilicon layer 109 contacted by via 151 is continuous with respect to polysilicon feature 171 in the material stack of resonator 102 (e.g., continuous by virtue of a tethering structure that connects/anchors the otherwise released MEMS resonator 102 to the surrounding/field area of the device), while single-crystal silicon region contacted by via 153 (through piezoelectric layer opening 163) is likewise contiguous with respect to single-crystal silicon layer 173 in the resonator material stack, meaning that contacts 152 and 154 are electrically coupled to regions 171 and 173, respectively, and thus to electrodes on either side of piezoelectric region 107 within MEMS resonator 102. Accordingly, a time-varying potential may be applied across contacts 152 and 154 to produce corresponding time-varying piezoelectric expansion and contraction of resonator piezoelectric layer to drive resonator 102 into mechanical resonance in one or more modes (e.g., extensional, flexural, shear, breath-mode, etc.). As discussed, other contacts and corresponding vias may be provided to effectuate resonator bias, device grounding, etc., and the contacts/vias shown may be used to convey signals and voltages other than resonator actuation signals (e.g., signals indicative of resonant motion, resistance of MEMS thermistor element, relative position of MEMS element within cavity 104, etc.).

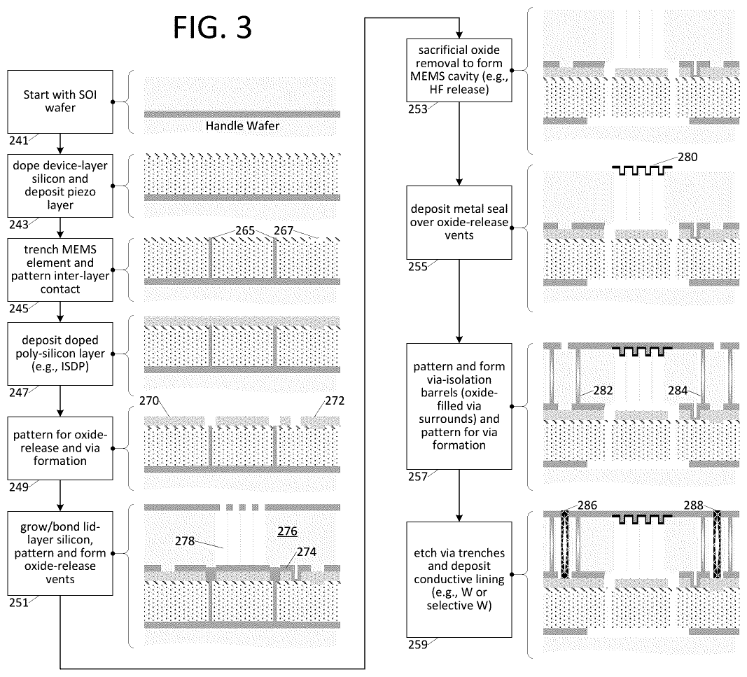

While vias 151 and 153 are depicted as trench-isolated conductors (i.e., metal such as tungsten (W) or selective tungsten extending through a trench between contact 152/154 and polysilicon layer 109—and optionally into polysilicon layer 109 as shown at 181—and electrically isolated by an oxide-filled barrel-trench 183), various other via structures may be implemented in alternative embodiments. In MEMS device embodiment 200 of FIG. 2, for example, vias 201 and 203 are formed by sputtered metal deposition on a sloped-wall trench—an approach that avoids the need for separate metal types/processes with respect to metal vent cover (seal) 105 and metal vias 201/203 (both may be implemented, for example, by the same sputtered metal). All the variations discussed above with respect to metal vent seal 105 apply equally in the embodiment of FIG. 2 and, more generally, vias formed as shown in FIG. 1 or 2 may be implemented with different vent-seal materials and/or processes, including narrow-passage epitaxial silicon vent seals as discussed below.

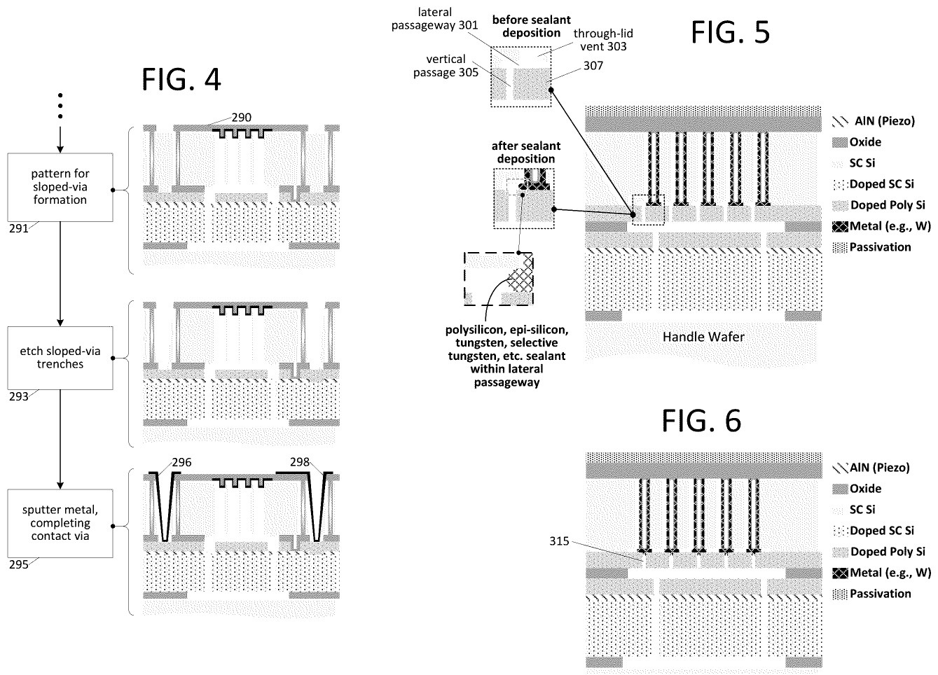

FIG. 3 illustrates an exemplary fabrication process with respect to the MEMS embodiment of FIG. 1. Starting from a silicon-on-insulator (SOI) structure at 241 (i.e., buried oxide sandwiched between single-crystal-silicon handle layer and single-crystal-silicon device layer), device-layer silicon is doped to a desired level (e.g., degenerately doped with an n-type impurity concentration of at least 1E19/cm³ in at least one embodiment) followed by deposition of piezoelectric layer at 243 (e.g., aluminum nitride (AlN), though other piezoelectric materials may be used). At 245, a trench 265 that defines the MEMS element (e.g., outlines MEMS resonator) is formed through dielectric layer and doped silicon layer (i.e., trench extending to the buried oxide, separating that resonator from surrounding sidewalls of the silicon device layer) and filled with sacrificial oxide, and a through-dielectric contact region 267 is patterned. Doped polysilicon is deposited at 247, then patterned at 249 to segregate contact regions 270 and 272 and prepare for eventual oxide release and conductive via formation. At 251, over-poly oxide layer 274 is deposited and patterned for contact formation, followed by deposition of lid-layer silicon 276 (e.g., deposited epitaxially, through wafer-bonding, etc.), patterning for release vent formation and then etching to form oxide-release vents 279. Hydrofluoric acid (HF) release or other oxide release is executed at 253 (e.g., generally a vapor etch using a bubbled hydrofluoric acid solution or anhydrous hydrofluoric acid gas, though any fluid-phase (gas/vapor or liquid) release-etch may be employed) to form the MEMS cavity, followed at 255 by deposition of metal seal 280 to seal the oxide-release vents—an operation carried out, for example, at relatively low temperature (less than 400° C. in a number of sputtered metal processes) and without problematic material deposition within the MEMS cavity. At 257, via-isolation barrels 282 and 284 are patterned, etched and filled with oxide, followed by surface oxide deposition and contact-via patterning. Via trenches are etched and lined (or filled with) conductive material at 259 (e.g., tungsten or selective tungsten, the latter depositing on single-crystal or polycrystalline silicon, but not oxide) to finish conductive vias 286 and 288—structures that may thereafter be overlaid with contact metal, followed by passivation to yield the FIG. 1 embodiment.

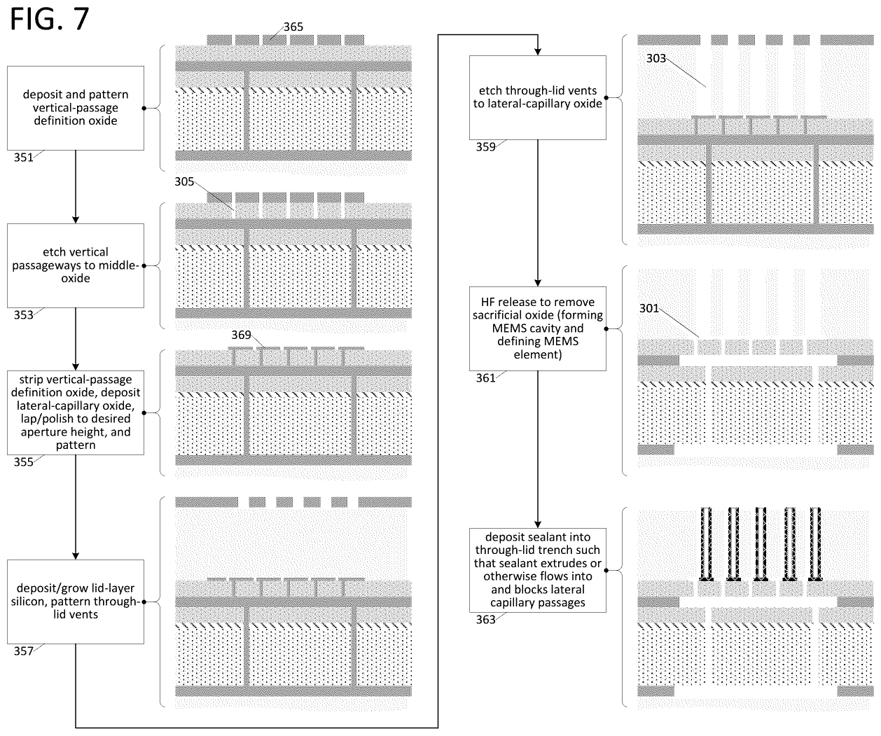

FIG. 4 illustrates an exemplary fabrication process with respect to tapered-via MEMS embodiment of FIG. 2—after oxide-release and release-vent sealing operations (e.g., as shown at 253 and 255 in FIG. 3) have been completed and via-isolation barrels have been formed. Surface oxide 290 is patterned (291) in preparation for tapered-via formation, followed by etching of sloped via trenches at 293. Metal is deposited at 295 (e.g., through sputtering) to complete contact vias 296 and 298, followed by passivation to yield the FIG. 2 embodiment.

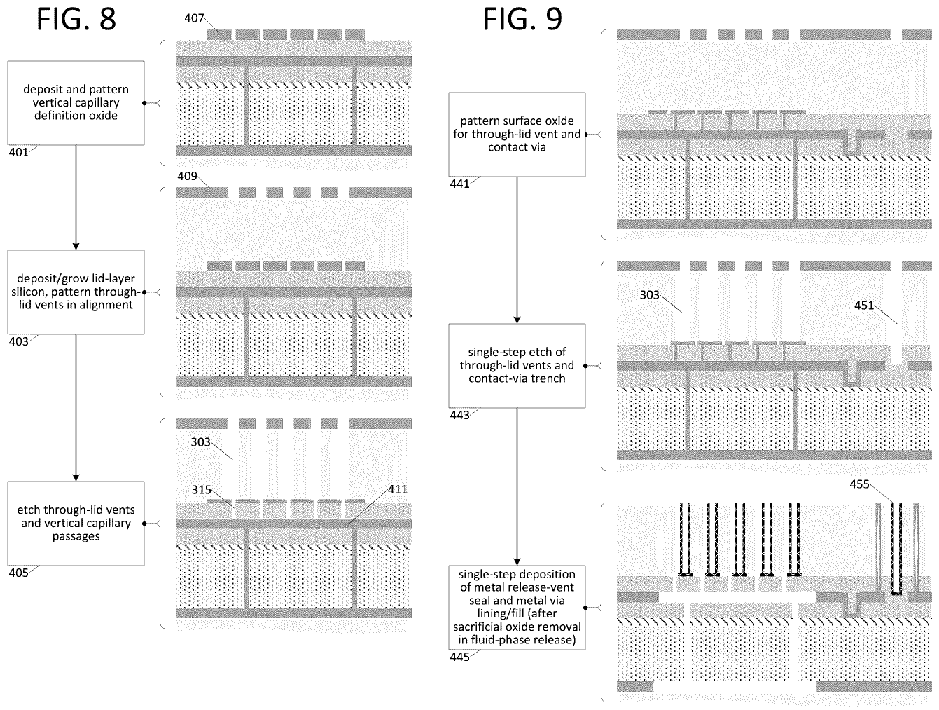

FIGS. 5 and 6 illustrate alternative embodiments in which oxide in the MEMS cavity is released through relatively small capillary passageways extending between the MEMS-element cavity and larger through-lid vents; passageways sufficiently narrow (constricted) to be closed off with relatively small sealant volume and to prevent propagation of vent sealant into the MEMS cavity itself.

In the embodiment of FIG. 5, the oxide-release path includes relatively narrow (high aspect-ratio) lateral passageways 301 that extend between through-lid vents 303 and vertical pathways 305 (the latter extending to/into the cavity through doped polysilicon layer 307 in this example) along respective axes substantially orthogonal to extensional axes of the passages they interjoin (i.e., vents 303 and vertical pathways 305)—a geometry that lacks line-of-sight passage from the lid-layer vent opening to the MEMS cavity and thus no straight-line path for undesired vent-sealant deposition into the MEMS cavity (i.e., vents 303 and pathways 305 extend/are routed along non-concentric parallel axes). Also, while the minimum aperture-size/aspect-ratio of through-lid vents 303 is generally constrained by requirements of the relatively deep etch through the silicon lid layer, lateral passageways 301 may be implemented with significantly smaller aperture height (e.g., less than 200 nanometers, or less than 100 nanometers) or higher length-to-aperture aspect ratio (e.g., as small as 9:1). Accordingly, lateral passageways 301 are readily plugged by various materials deposited to line or fill the through-lid trench including, without limitation, polysilicon, epitaxial silicon, tungsten, selective tungsten and so forth. Moreover, in the case of epitaxial silicon deposition, temperatures may be reduced relative to those effected by less restrictive (larger aperture) release vents, avoiding (or at least mitigating) degradation of temperature susceptible material layers. In any case, sealant material deposited into the through-lid vent paths extrudes (or otherwise flows) into the lateral-passageways, blocking those capillaries to hermetically seal the MEMS cavity.

In the embodiment of FIG. 6, narrow, small-aperture passageways 315 are formed vertically directly beneath the larger-aperture through-lid vents—a capillary “straw” approach that exposes line-of-sight access into the MEMS cavity in return for potentially simplified fabrication. That is, each passageway 305 extends (is routed) along an axis through which the adjoined through-lid vent also extends—a shared axis that may or may not be concentric with respect to either segment of the collective pathway. As in the embodiment of FIG. 5, narrow (capillary) passageways 315 are dimensioned to permit fluid-phase oxide removal while limiting through-passage of sealant material (e.g., tungsten, selective tungsten, polysilicon, epitaxial silicon, etc.), permitting sufficient ingress into the capillary to seal the oxide-release vent without (or with negligible) sealant entry into the MEMS cavity.

Still referring to FIG. 6, the leftmost capillary passageway 315 and corresponding through-lid vent are positioned over the field area of the MEMS device and not over the MEMS cavity itself. This arrangement may further reduce propagation of sealant into the MEMS cavity and may be applied with respect to any or all the oxide-release vents in the FIG. 6 embodiment. More generally, over-field-area release-vent placement may be implemented with respect to any of the embodiments presented herein—that is, any or all oxide-release vents or component passages thereof may be disposed over the field area in such embodiments (e.g., outside the perimeter defined by the trench through the device-layer silicon) instead of over the MEMS cavity.

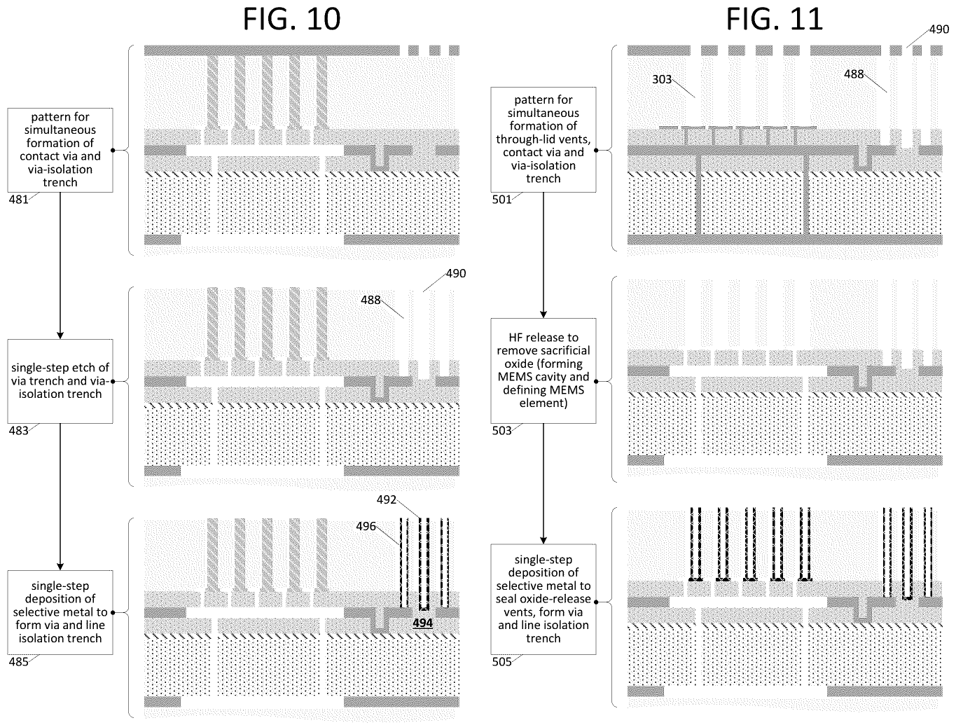

FIGS. 7 and 8 illustrate exemplary fabrication processes corresponding to the narrow-passageway oxide-release vents shown in FIGS. 5 and 6, respectively. Starting at 351 in FIG. 7, vertical-passage definition oxide 365 is deposited (in this case over doped polysilicon) and patterned, followed by vertical passageway etch at 353. In the depicted embodiment, the vertical passageways (305) are themselves dimensioned as capillary (narrow aperture, high aspect ratio) passages, though larger-aperture vertical passageways may be implemented. At 355, the vertical-passage definition oxide is stripped followed by deposition, an optional back-grind (or lap, polish or other practicable planarizing ablation) and patterning of lateral-capillary oxide 369 to yield a desired lateral capillary passage height. At 357, lid-layer silicon is deposited (e.g., wafer bond, epitaxial growth, etc.) followed by deposition of sacrificial surface oxide and patterning for ensuing etch at 359 to form through-lid vents 303. Vapor-phase or liquid-phase oxide release (e.g., vapor-phase HF release) is carried out at 361 to remove sacrificial oxide, including the lateral-capillary oxide (leaving lateral capillary passages 301), vertical-passage oxide and sacrificial oxides within the MEMS cavity. At 363, vent-sealant material (e.g., tungsten, selective tungsten, polysilicon, epitaxial silicon, etc.) is deposited into the through-lid vents, extruding (or otherwise flowing) into and hermetically sealing the lateral capillary passageways (and thus sealing the MEMS cavity).

Turning to the capillary-straw formation in FIG. 8, vertical-capillary definition oxide 407 is deposited (in this case over doped polysilicon) and patterned to yield a desired capillary aperture dimension at 401. Though not specifically shown, capillary definition oxide 407 may be back-ground (lapped, polished, etc.) to enable reduced aperture dimension relative to that achievable through thicker oxide layers. In any case, lid-layer silicon is deposited at 403, followed by deposition and patterning of surface oxide 409 to enable formation of through-lid vents axially aligned (or otherwise disposed in line) with apertures in capillary definition oxide 407. Accordingly, deep-trench etching at 405 yields through-lid vents 303 in alignment with capillary passages 315 to interstitial oxide 411. Fluid-phase oxide release may be carried out thereafter to remove sacrificial oxide and form the MEMS cavity followed by sealant deposition into the lid-layer trenches to seal the vertical capillary passages as shown in FIG. 6.

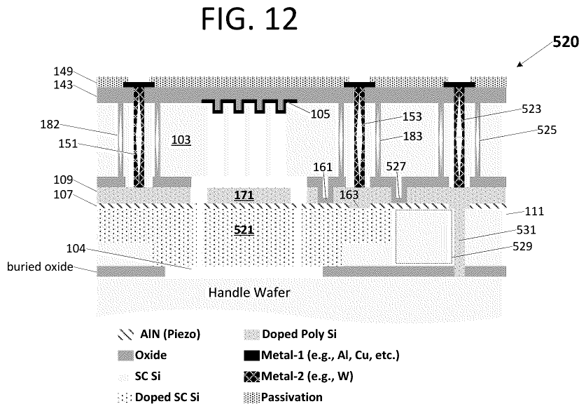

FIGS. 9-11 illustrate examples of process efficiency achieved through concurrent feature formation with respect to the capillary oxide-vent embodiments of FIGS. 5 and 6. Referring first to FIG. 9 (depicted in the context of lateral capillary embodiment of FIG. 5, but equally applicable to vertical capillary embodiment of FIG. 6 as well as embodiments that lack capillary oxide-release passageways), the surface oxide is patterned at 441 for formation of both through-lid vents and contact vias (patterning for only one contact-via being depicted). A single etching step is then carried out at 443 to form both through-lid vents 303 and contact via trench 451, followed by a single-step deposition of a highly conductive material such as metal or highly-doped silicon at 445 to both seal the release vents (e.g., within narrow lateral passageways in the embodiment shown, or within narrow vertical passageways in the vertical capillary process) and form contact via 455. Though not specifically shown, subsequent etching and oxide deposition may be carried out to form via isolation structure (surrounding contact via 455), followed by surface contact deposition and passivation deposition to complete the MEMS device.

In the exemplary process flow of FIG. 10, a surface oxide is patterned (after oxide-release and vent-seal) at 481 to enable formation of conductive-via and via-isolation trenches, followed by single-step (concurrent or simultaneous) etching of those trenches at 483 (yielding isolation trench 488 and via trench 490). At 485, selective metal (e.g., selective tungsten or other conductive material that will deposit on silicon or polysilicon, but not oxide) is deposited concurrently (in a single deposition step) within via trench 490 and isolation trench 488, forming a conductive via 492 that extends to polysilicon region 494 and simultaneously lining the sides but not the oxide-layer stop of the via-isolation trench. The conductive isolation lining (496) may, in some embodiments, be coupled to ground or other reference potential to form a shielded conductive path through the MEMS device layers (in which case the conductive isolation 496 may electrically isolated from other regions of the MEMS device by one or more other isolation structures). As in FIG. 9, surface-contact and passivation depositions may be carried out to complete the MEMS device with the surface-contact metal isolated from via-isolation lining 496 by an oxide or other dielectric.

In the FIG. 11 process flow example, a surface oxide is patterned at 501 to enable concurrent formation of through-lid release vents 303, via-isolation trench 488 and contact-via trench 490, followed by a single-step etch to form those structures. Vapor-phase or liquid-phase oxide release (e.g., HF release) is carried out at 503 to remove (evacuate, eliminate, rid) sacrificial oxide, including the lateral-capillary oxide (leaving lateral capillary passages), vertical-passage oxide and sacrificial oxides within the MEMS cavity. At 505, a selective-metal or highly-doped silicon is deposited concurrently within the through-lid release vents, the via trench and the isolation trenches, sealing the lateral oxide-release passageways (i.e., as discussed above), forming the conductive via and isolating the via in a single material deposition step. As before, surface-contact and passivation depositions may be executed to complete the MEMS device.

For MEMS resonators implemented with silicon and piezoelectric material layers (e.g., aluminum nitride as the piezoelectric layer), the temperature dependence of the silicon layer's elastic modulus and thus the temperature dependence of the resonator frequency may be reduced by degenerately doping the silicon. In some MEMS devices, it may be desirable to dope regions of the silicon structural layer to enable ohmic contact to deposited materials (e.g., metals, doped semiconductors) or to otherwise modify their mechanical and/or electrical properties. Although high dopant concentrations can be achieved through surface diffusion-doping (i.e., deposition of a dopant source such as phospho-silicate glass or boro-silicate glass on the silicon layer surface, followed by a high temperature thermal drive or anneal), dopant penetration for practicable thermal drive periods tends to be limited (and/or require prohibitively long drive periods for silicon layers thicker than ˜5-6 μm).

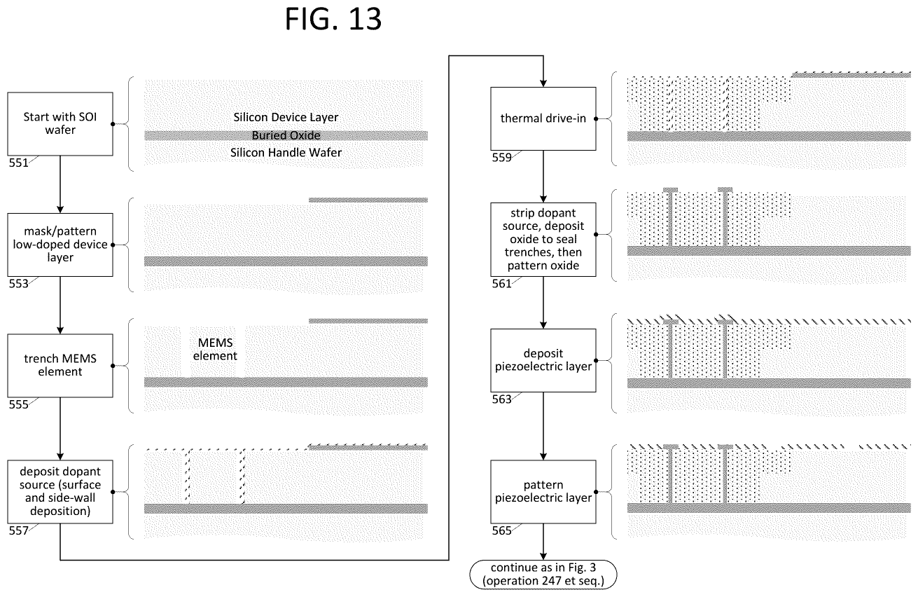

In embodiments shown in FIGS. 12-14, doping (including degenerate doping) depth for a thermal drive of a given duration is increased by etching or otherwise forming slots within the silicon layer and depositing a dopant-source film on the sidewalls of the slots prior to the thermal drive. Through this lateral doping approach (which may be combined with surface-layer doping) the diffusion time is only limited by the spacing of the slots rather than the thickness of the silicon film. The slots may also serve a dual purpose—not only enabling more rapid (or deeper) doping, but also defining the silicon MEMS structure of the resonator (i.e., defining sides of the silicon portion of the resonant MEMS structure).

In a number of processes, formation of dopant-delivery slots in the silicon layer may enable subsequently deposited and patterned materials (e.g., piezoelectric material layer) to occupy the slots—an undesirable result, particularly where the slots separate the resonant MEMS structure from the surrounding silicon. On the other hand, forming dopant-delivery slots and executing the diffusion drive cycle after piezoelectric material deposition may subject the piezoelectric film to a prohibitively high (i.e., degradative) temperature.

In embodiments depicted in FIGS. 12-14, lateral doping challenges are overcome through a slot cap-off approach in which a silicon oxide film is deposited over dopant-delivery slots (i.e., after dopant has been deposited on silicon sidewalls defined by the slots and thermally diffused into the silicon layer) prior to surface deposition of piezoelectric or other material layers. Through this approach, the piezoelectric material and/or other material layers may be deposited and patterned without fouling the slots or exposure to diffusion-drive temperatures. In general, the slot-capping silicon oxide film is sufficiently thick to cover (and/or partially or completely fill) the dopant-delivery slots (trenches) and may be etched or polished back to a reduced thickness. In a number of embodiments, for example, the silicon oxide is completely removed from the silicon surface (leaving it only in the slots) prior to deposition of piezoelectric or other material layers. In other embodiments, the silicon oxide layer is patterned and a piezoelectric film (e.g. aluminum nitride) is deposited on top. Additional layers such as polysilicon (including degenerately doped polysilicon) and further oxide may be deposited and patterned over the piezoelectric layer to create electrodes, diodes and/or other structures. The piezoelectric film may be patterned prior to and/or after deposition of these additional layers. Other oxide films may be used to cap-off dopant delivery slots in alternative embodiments.

FIG. 12 illustrates an embodiment of a MEMS device 520 having a laterally-doped (e.g., degenerately n-doped), piezoelectrically-actuated MEMS resonator 521—that is, a MEMS resonator 521 subject to dopant drive-in through resonator sidewalls (at least) prior to deposition of piezoelectric layer 107. Features above piezoelectric layer 107, including metal release-vent seal 105, through-silicon vias 151, 153 and 523 and corresponding isolation structures 181, 183 and 525, surface oxide 143, passivation layer 149, middle-oxide isolation features at 161 and 527) and doped polysilicon region 171 are implemented generally as discussed above (e.g., in reference to FIG. 1). As in FIG. 1, electrical vias 151 and 153 extend through the lid-layer silicon 103 to contact sub-surface structures (e.g., MEMS resonator drive/sense electrode(s), MEMS resonator-bias electrode(s), thermistor terminals, MEMS accelerometer-mass bias/sense electrodes, etc.), while via 523 extends to an isolated region of doped-polysilicon layer 109 (isolated by oxide feature 527) and thus, by way of doped-poly trench-fill 531, to the handle wafer (e.g., extending through the buried oxide layer to ground the handle, provide electrical shielding, etc.).

In the specific embodiment shown, region 529 of single-crystal silicon device layer 111 is masked during doping of resonator feature 521 and thus remains undoped (or lightly n-doped or lightly p-doped) to enable formation of additional features (electrostatic discharge protection elements and/or one or more other MEMS structures such as resonators, thermistors, etc.). In alternative embodiments, undoped region 529 may be trenched prior to piezoelectric layer deposition (e.g., to define other MEMS structures), or may include other more localized depositions and/or diffusions (e.g., one or more n-doped regions to form diode(s) within an electrostatic discharge protection element. Where no such other MEMS structures or diode-isolation regions are needed, undoped region 529 may be omitted altogether.

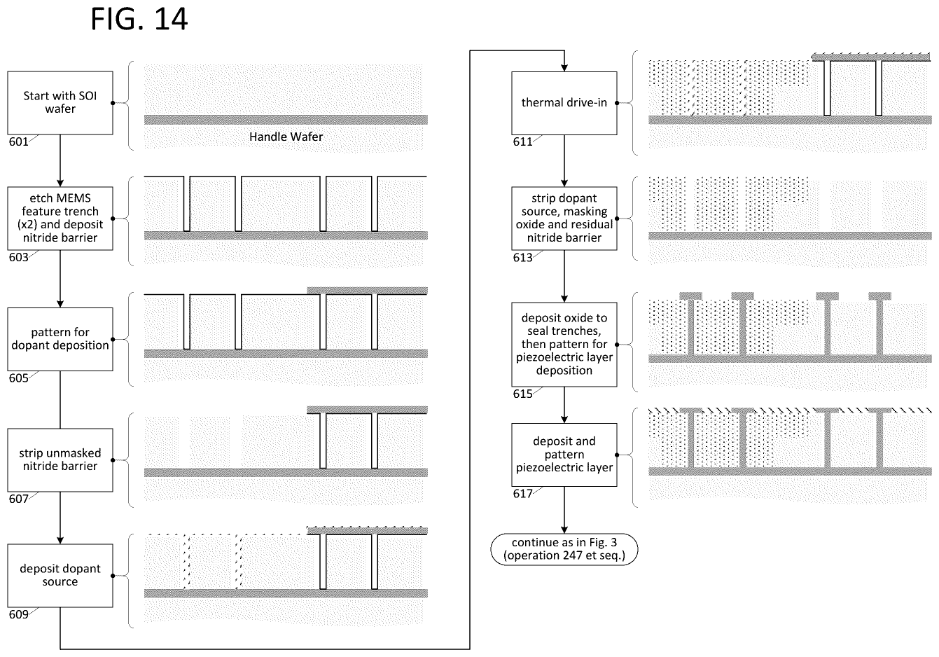

FIG. 13 illustrates an exemplary process flow for implementing MEMS device 520 of FIG. 12, starting with a silicon-on-insulator wafer as shown at 551. At 553, oxide is deposited and patterned over the silicon device layer to avoid subsequent dopant diffusion into the region thereunder and thus maintain a low-doped/non-doped silicon region. One or more trenches are etched within the device-layer silicon at 555 to define at least one MEMS element, followed by deposition of a dopant source on the surface and trench side-walls as shown at 557. Accordingly, following a thermal anneal or drive-in at 559, dopant diffuses laterally into the MEMS element and into the adjacent field areas. In one embodiment, the MEMS element is dimensioned with a relatively narrow width (e.g., less than 12 [symbol] m) such that dopant diffuses all the way through the MEMS element. In such an embodiment, dopant deposition may be masked at the surface of the MEMS element (and from the surface of the adjacent field area if desired). In any case, the dopant source is stripped at 561, followed by oxide deposition to seal the trenches and oxide patterning in preparation for piezoelectric layer deposition. At this point, the silicon device layer is constituted by distinct doped and undoped regions-the former being doped to any practicable dopant concentration (e.g., above 1E19/cm³, 1E20/cm³, 2E20/cm³, or higher concentration of n-type or p-type dopant). The piezoelectric layer is deposited at 563 and then patterned for electrical (via) interconnect at 565. At this point, features above the piezoelectric layer may be formed (deposited, etched or otherwise fabricated) generally as shown in FIG. 3 (e.g., operations starting at process step 247).

FIG. 14 illustrates another exemplary process for fabricating MEMS device 520 of FIG. 12, again starting with a silicon-on-insulator wafer (601). At 603, one or more trenches are etched to define MEMS features (two trenches in this case) and a nitride barrier (e.g., silicon nitride) is deposited—lining the trench walls or otherwise plugging the trenches as shown. At 605 oxide is deposited and patterned in preparation for dopant deposition, followed by stripping unmasked nitride barrier at 607. At 609 dopant source is deposited, lining the trench walls and unmasked surface of the silicon device layer as shown. Thermal drive-in is carried out at 611 to yield the doped single-crystal silicon pattern shown in MEMS device 520, while maintaining undoped region beneath the oxide/nitride mask. At 613 the dopant source, masking oxide and residual nitride barrier are stripped and, at 615, oxide is deposited to seal the trenches and then patterned in preparation for piezoelectric layer deposition. The piezoelectric layer is deposited and 617 and patterned in preparation for electrical interconnect formation. As in the FIG. 13 fabrication process, features above the piezoelectric layer may be formed at this point generally as shown starting at 247 in FIG. 3.

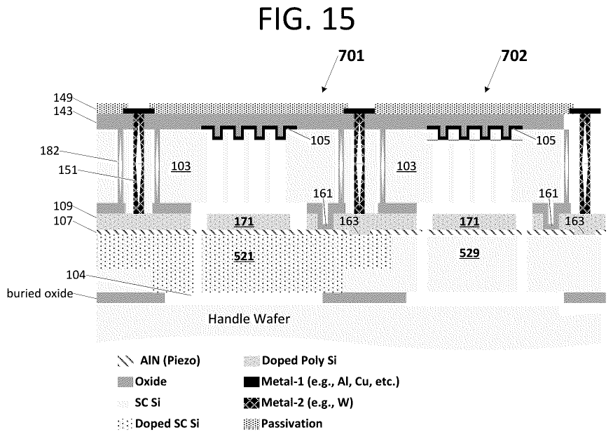

Referring to FIG. 15, the MEMS elements formed within the differently doped regions of the silicon device layer may include, for example and without limitation, two different MEMS resonators 701 and 702 having substantially/purposefully different temperature-coefficients of frequency (TCF) and/or one or more MEMS resonator in combination with an alternative MEMS element such as a thermistor, accelerometer mass, optical feature, and so forth. Where two MEMS resonators are implemented, the resonator within the more heavily doped device-layer silicon region (e.g., having a dopant concentration of 1E19/cm3 or higher and a dopant concentration 10, 100, 1000 or more times the dopant concentration of the undoped/lightly-doped region of the device-layer silicon) may have substantially reduced temperature sensitivity relative to the resonator implemented within the less doped silicon region, for example, to enable temperature detection (or temperature-change detection) based on comparison or other evaluation of the resonant frequencies. In one embodiment, for example, the first-order TCF of the temperature-sensitive resonator (e.g., implemented within the less-doped silicon region) is at least 10 times (or 100 times or more) the first-order TCF of the less-temperature-sensitive resonator.

In the foregoing description and in the accompanying drawings, specific terminology and drawing symbols have been set forth to provide a thorough understanding of the disclosed embodiments. In some instances, the terminology and symbols may imply specific details not required to practice those embodiments. For example, any of the specific materials, dimensions (thicknesses), concentrations, operational order (e.g., order of device fabrication steps), temperatures and the like can be different from those described above in alternative embodiments. Oxides may include various silicon oxides (e.g., silicon dioxide (SiO₂, silicon oxynitride (SiOₓN_{y}), etc.) and/or other dielectric materials compatible with silicon wafer processing. The term “coupled” is used herein to express a direct connection as well as a connection through one or more intervening functional components or structures. The terms “exemplary” and “embodiment” are used to express an example, not a preference or requirement. Also, the terms “may” and “can” are used interchangeably to denote optional (permissible) subject matter. The absence of either term should not be construed as meaning that a given feature or technique is required.

Various modifications and changes can be made to the embodiments presented herein without departing from the broader spirit and scope of the disclosure. For example, features or aspects of any of the embodiments can be applied in combination with any other of the embodiments or in place of counterpart features or aspects thereof. Accordingly, the specification and drawings are to be regarded in an illustrative rather than a restrictive sense.

1. (canceled)

2. A method of fabricating an integrated circuit without exposing a piezoelectric material layer to a high temperature associated with a drive-in doping process, the integrated circuit having a microelectromechanical systems (MEMS) device, the MEMS device having a body which is free to move or deflect, under influence of the piezoelectric material layer, during operation of the integrated circuit, the method comprising:
processing a layer of crystal silicon, the layer of crystal silicon having a first surface, to define one or more slots or trenches that extend orthogonally into the layer of crystal silicon in a direction, relative to the first surface;
depositing a dopant source material to cover sidewalls within the one or more slots or trenches;
performing the drive-in doping process, including heating the layer of crystal silicon and the deposited dopant source material to the high temperature, so as to cause transfer of a dopant from the dopant source material into the layer of crystal silicon via the sidewalls;
depositing a cap-off material to block ingress into the one or more slots or trenches;
forming the piezoelectric material layer over the first surface and the cap-off material;
removing the cap-off material; and
hermetically sealing a cavity within the integrated circuit, the cavity formed at least in part by the one or more slots or trenches.

3. The method of claim 2 wherein the method further comprises patterning the piezoelectric material layer prior to hermetically sealing the cavity.

4. The method of claim 2 wherein the integrated circuit comprises a lid layer, the lid layer having a vent extending through the lid layer, and wherein hermetically-sealing the cavity comprises sputtering a metal material so as to pass into and occlude at least a portion of the vent.

5. The method of claim 4 wherein the vent comprises at least one right-angle bend which obscures line of sight access between the cavity and an atmospheric environment external to the lid layer.

6. The method of claim 4 wherein the vent is an etch-release vent, and wherein the method further comprises removing a buried oxide material, through the lid layer and via the vent, to at least partially define the cavity.

7. The method of claim 2 wherein depositing the dopant source material is also performed so as to cover the first surface, and wherein performing the drive-in doping process is to also cause the transfer of the dopant into the layer of crystal silicon via the first surface.

8. The method of claim 2 wherein performing the drive-in doping process is performed so as to degenerately-dope the layer of crystal silicon, and to thereby form an electrode of the body, the electrode to perform at least one of actuation of or sensing motion of the body.

9. The method of claim 2 wherein the piezoelectric material layer comprises at least one of aluminum nitride or lead-zirconium-titanate.

10. The method of claim 2 wherein the dopant comprises phosphorus.

11. The method of claim 2 wherein the body is a first MEMS body and wherein the integrated circuit also has a second MEMS body, at least one of the first MEMS body or the second MEMS body being part of a resonator, wherein each of the first MEMS body and the second MEMS body comprises a respective portion of the layer of crystal silicon and wherein performing the drive-in doping process is performed simultaneously with respect to the respective portions, so as to thereby simultaneously dope a portion of each of the first MEMS body and the second MEMS body.

12. The method of claim 2 wherein the integrated circuit comprises a vent extending through a lid layer and a through-layer via, and wherein hermetically sealing the cavity comprises depositing a material in a manner so as to simultaneously occlude the vent and form part of the through-layer via.

13. The method of claim 2 wherein the integrated circuit comprises two layers of degenerately-doped crystal silicon and wherein performing the drive-in doping process comprises degenerately-doping at least one of the two layers of degenerately-doped crystal silicon.

14. The method of claim 13 wherein a first one of the two layers is predominantly single-crystal silicon and a second one of the two layers is predominantly polycrystal silicon.

15. A method of fabricating an integrated circuit without exposing a piezoelectric material layer to a high temperature associated with a drive-in doping process, the integrated circuit having two microelectromechanical systems (MEMS) devices, including a MEMS resonator having a body which is free to move or deflect, under influence of the piezoelectric material layer, during operation of the integrated circuit, the method comprising:
processing a layer of crystal silicon, the layer of crystal silicon having a first surface, to define one or more slots or trenches that extend orthogonally into the layer of crystal silicon in a direction, relative to the first surface;
depositing a dopant source material to cover sidewalls within the one or more slots or trenches;
performing the drive-in doping process, including heating the layer of crystal silicon and the deposited dopant source material to the high temperature, so as to cause transfer of phosphorus from the dopant source material into the layer of crystal silicon via the sidewalls;
depositing a cap-off material to block ingress into the one or more slots or trenches;
forming the piezoelectric material layer over the first surface and the cap-off material;
removing the cap-off material; and
hermetically sealing a cavity within the integrated circuit, the cavity formed at least in part by the one or more slots or trenches.

16. The method of claim 15 wherein the MEMS resonator is a first MEMS resonator and wherein the two MEMS devices further include at least one of a temperature sensing device or a second MEMS resonator, the at least one of the temperature sensing device or the second MEMS resonator having a second body, wherein each of the body of the first MEMS resonator and the second body comprises a respective portion of the layer of crystal silicon and wherein performing the drive-in doping process is performed simultaneously with respect to the respective portions, so as to thereby simultaneously dope a portion of each of the body of the first MEMS resonator and the second body.

17. The method of claim 16 wherein the method further comprises doping the respective portions so as to have different concentrations of phosphorus dopant, such that a resultant phosphorus dopant concentration of a first one of the respective portions is at least ten times greater than a resultant phosphorus dopant concentration of a second one of the respective portions.

18. The method of claim 15 wherein depositing the dopant source material is also performed so as to cover the first surface, and wherein performing the drive-in doping process is to also cause the transfer of the dopant into the layer of crystal silicon via the first surface.

19. The method of claim 15 wherein performing the drive-in doping process is performed so as to degenerately-dope the layer of crystal silicon, and to thereby form an electrode of the body of the MEMS resonator, the electrode to perform at least one of actuation of or sensing motion of the MEMS resonator.

20. A method of fabricating an integrated circuit without exposing a piezoelectric material layer to a high temperature associated with a drive-in doping process, the integrated circuit having a microelectromechanical systems (MEMS) device, the MEMS device having a body which is free to move or deflect, under influence of the piezoelectric material layer, during operation of the integrated circuit, the method comprising:
processing a layer of single crystal silicon, the layer of single crystal silicon having a first surface, to define one or more slots or trenches that extend orthogonally into the layer of single crystal silicon in a direction, relative to the first surface;
depositing a dopant source material to cover sidewalls within the one or more slots or trenches;
performing the drive-in doping process, including heating the layer of single crystal silicon and the deposited dopant source material to the high temperature, so as to cause transfer of a dopant from the dopant source material into the layer of single crystal silicon via the sidewalls and thereby degenerately-dope the layer of single crystal silicon;
depositing a cap-off material to block ingress into the one or more slots or trenches;
forming the piezoelectric material layer over the first surface and the cap-off material;
removing the cap-off material; and
hermetically sealing a cavity within the integrated circuit, the cavity formed at least in part by the one or more slots or trenches.

21. The method of claim 20 wherein the piezoelectric material layer directly abuts the layer of single crystal silicon.
